(19) United States
(12) Patent Application Publication
(10) Pub. No.: US 2021/0302652 A1
(43) Pub. Date: Sep. 30, 2021

(54) TECHNOLOGIES FOR PHOTONIC DEMULTIPLEXERS

(71) Applicant: Intel Corporation, Santa Clara, CA (US)

(72) Inventors: Boris M. Vulovic, Campbell, CA (US); Tiehui Su, San Jose, CA (US); Nutan Gautam, Los Gatos, CA (US); Wenhua Lin, Fremont, CA (US); Mehbuba Tanzid, San Jose, CA (US); Ansheng Liu, Cupertino, CA (US); Wei Qian, Walnut, CA (US)

(73) Assignee: Intel Corporation, Santa Clara, CA (US)

(21) Appl. No.: 17/343,280

(22) Filed: Jun. 9, 2021

(51) Int. Cl. G02B 6/12

(52) U.S. Cl. CPC G02B 6/12019; G02B 6/2938

(57) ABSTRACT

Techniques for photonic demultiplexers are disclosed. In the illustrative embodiment, an output of an unbalanced interferometer formed from waveguides is positioned to the input of a slab grating, with several output waveguides collecting light in different wavelength ranges to create different channels for the demultiplexer system. In some embodiments, one or more auxiliary structures may be positioned near the input of the grating to change the structure of the spatial modes being provided as an input to the grating in order to alter the spectra of the output channels.

### BACKGROUND

Multiplexed optical signals can carry enormous amounts of data. However, the different channels of a multiplexed optical signal are typically physically separated in order to be sensed. Performance characteristics of multiplexers and demultiplexers include insertion loss, bandwidth, spacing between channels, and bandpass flatness.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a top view of one embodiment of demultiplexer system with a Mach-Zehnder interferometer and an echelle grating;

FIG. 2 is a plot showing insertion loss as a function of wavelength for different channels of one embodiment of the demultiplexer system of FIG. 1;

FIG. 3 is a plot showing insertion loss as a function of wavelength for different channels of one embodiment of the demultiplexer system of FIG. 1;

FIG. 4 is a top view of one embodiment of demultiplexer system with a Mach-Zehnder interferometer and an echelle grating with an auxiliary structure near an input of the echelle grating;

FIG. 5 is a perspective view of input waveguides and the auxiliary structure of the demultiplexer system of FIG. 4;

FIG. 6 is a cross-section view of the input waveguides and the auxiliary structure of the demultiplexer system of FIG. 4;

FIG. 7 is a cross-section view of the input waveguides and the auxiliary structure of the demultiplexer system of FIG. 4;

FIG. 8 is a plot showing insertion loss as a function of wavelength for different channels of one embodiment of the demultiplexer system of FIG. 4;

FIG. 9 is a plot showing insertion loss as a function of wavelength for different channels of one embodiment of the demultiplexer system of FIG. 4;

FIG. 10 is a top view of one embodiment of demultiplexer system with a Mach-Zehnder interferometer and an arrayed waveguide grating;

FIG. 11 illustrates an embodiment of a block diagram for a computing system including a multicore processor; and

FIG. 12 illustrates an embodiment of a block for a computing system including multiple processors.

### DETAILED DESCRIPTION OF THE DRAWINGS

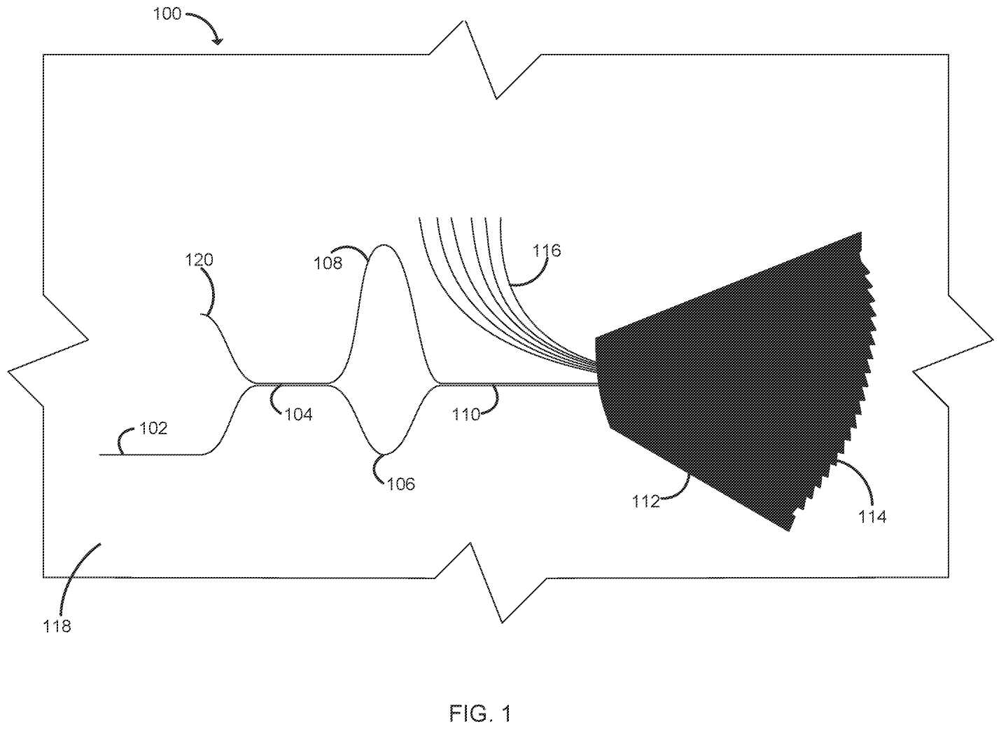

In the illustrative embodiment, as explained in more detail below in regard to FIG. 1, an output of a Mach-Zehnder interferometer (MZI) in a waveguide is positioned at the input of a slab echelle grating (EG) with several output channels. The MZI is designed to have a free spectral range (FSR) equal to the channel spacing of the EG. Additionally, the MZI steers the beam position at the input of the EG in such a way that, as the wavelength is scanned over a passband of a channel, the focal point at the output of the EG stays at the position of the output waveguide. This produces a relatively flat-top transmission spectrum for the given channel. As the MZI's FSR is equal to the channel spacing of the EG, this repeats for all the output waveguide of the EG and hence the transmission for all the channels is approximately a flat-top spectrum.

In the illustrative embodiment, the output waveguides are single-mode waveguides. The relative small size of single-mode waveguides in the output reduces the overall footprint of the photonic integrated chip. Additionally, the single-mode waveguides can be coupled to relatively small waveguide photodetectors, which have a lower RC constant (and, therefore, faster performance) due to the relatively small size.

As discussed in more detail below, the bandwidth of each channel can be increased by increasing the spacing between the waveguides that form the coupler at the input to the grating. However, increasing that spacing also causes a dip in the symmetric supermode of the coupled waveguides, causing lower coupling of the symmetric supermode to the output and a ripple to form in the passband. To reduce or eliminate the dip in the symmetric supermode, a coupler architecture with a tapering structure formed by grayscale lithography in the gap between the waveguides is used. This structure reduces the insertion loss and the ripple in the passband when the waveguides of the coupler are separated far apart to a give wider bandwidth while reducing or eliminating any ripple.

Referring to FIG. 1, an embodiment of a demultiplexer system 100. The system 100 includes an input waveguide 102. The input waveguide 102 is connected to a coupler 104, which splits light from the input waveguide 102 into a second waveguide 106 and a third waveguide 108. The second waveguide 106 and the third waveguide 108 form paths of different lengths and are then brought together in a coupler 110. The second waveguide 106 and the third waveguide 108 are provided as an input to an echelle grating 112. Light from the second waveguide 106 and the third waveguide 108 expand as it propagates from the waveguides 106, 108 towards a reflective surface 114. The light reflects off of the reflective surface 114 in a direction that is dependent on the wavelength of the light and is focused onto one of several output waveguides 116.

Each of the output waveguides 116 captures a different range of input wavelengths. With only a single-mode waveguide as an input, each output waveguide 116 would act as a spectral filter with approximately a Gaussian shape, which is not a desirable shape for a spectral filter for many applications.

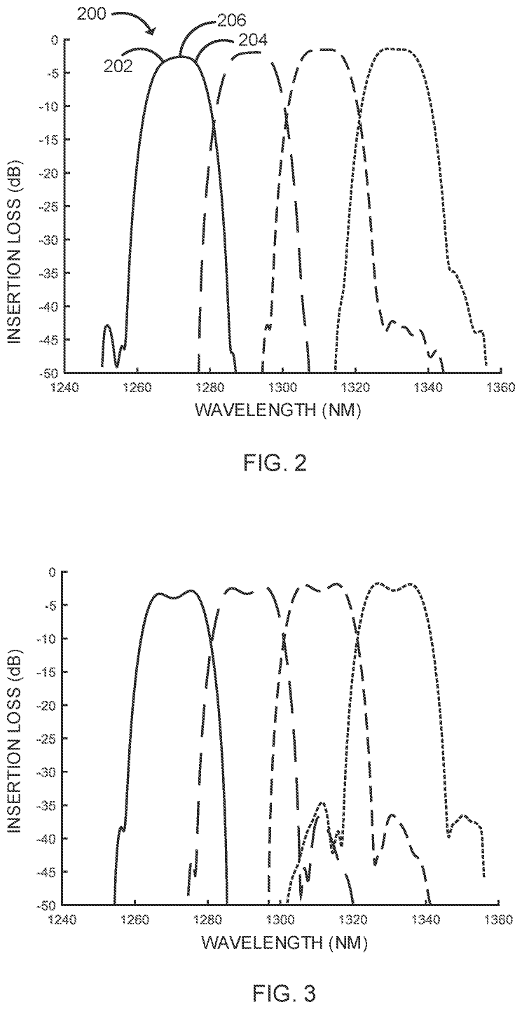

In order to improve the shape of the spectra coupled to the output waveguides 116, the unbalanced Mach-Zehnder interferometer formed by the coupler 104, waveguide 106, waveguide 108, and the coupler 110 is used to give a flatter spectrum, such as that shown in FIG. 2. In the illustrative embodiment, each of waveguide 106 and waveguide 108, when separated from each other, support a single spatial mode. In the coupler 110, the modes of the waveguide 106 and the waveguide 108 mix, and the waveguides 106, 108 together support two eigenmodes (called supermodes), one of which is symmetric and one of which is antisymmetric.

Considering the spectrum for a channel 200 shown in FIG. 2, at the position of the input to the grating 112, at the low cut-off wavelength 202 of the channel 200, the combination of the supermodes results in light that is mostly in the waveguide 108. The light at the wavelength 202 will reflect off of the reflective surface 114 and be reflected towards the output waveguides 116. The output waveguide 116 corresponding to the channel 200 is positioned to gather the light reflected at the low cut-off wavelength 202 of the channel 200.

At the high cut-off wavelength 204 of the channel 200, the input light is also reflected onto the same output waveguide 116 as for the light at wavelength 204. Two separate effects influence the position of the light at wavelength 204 that cancel out. One effect is that the reflective surface 114 will reflect the wavelength 204 slightly differently than it will wavelength 202 due to the dispersive property of diffraction gratings. The second effect is due to interference of the supermodes supported by the waveguides 106, 108. At the wavelength 204, the relative phase of the supermodes is shifted as compared to the wavelength 202, resulting in light that is mostly in the waveguide 106, shifting the light at the input by the amount the waveguides 106, 108 are separated. The system 100 is designed so that the shift in the position of the light between wavelength 202 and wavelength 204 caused by the reflective surface 114 matches the shift in position caused by the separation between the waveguides 106, 108. As a result, light at both wavelength 202 and wavelength 204 is passed into the output waveguide 116 for the channel 200 with a relatively low insertion loss.

At wavelength 206 between the low cut-off wavelength 202 and the high cut-off wavelength 204, the phase between the supermodes at the input waveguides 106, 108 is such that the mode of the light at the wavelength 206 has a bright spot between the waveguides 106, 108, leading to high coupling of light at the wavelength 206 to the output waveguide 116 corresponding to the channel 200.

In one embodiment, the demultiplexer system 100 is designed to have a particular spacing between channels, such as a spacing of 20 nanometers between the center wavelength of channels near 1,300 nanometers, which corresponds to a frequency spacing of about 3.55 terahertz. The difference in path lengths between waveguide 106 and waveguide 108 is such that the free spectral range of the interferometer matches the spacing between channels (i.e., 3.55 terahertz). As a result, the effect described above in regard to the channel 200 that gives a flatter spectrum also is in place for each other channel of the demultiplexer system 100.

Each waveguide 102, 106, 108, 116 may be a waveguide of any suitable size. For example, in one embodiment, each waveguide 102, 106, 108, 116 may have a rectangular cross-section with a width of 0.8 micrometers and a height of 0.35 micrometers. In other embodiments, each waveguide 102, 106, 108, 116 may have any suitable dimensions, such as a width of 0.1-10 micrometers and/or a height of 0.1-10 micrometers, or any suitable shape, such as rectangular, square, circle, half-circle, trapezoid, rib waveguide, ridge waveguide, etc. In some embodiments, any or all of waveguide 102, 106, 108, 116 may be polarization-insensitive waveguides, such as by having a core with a height and a width larger than 1.5 micrometers.

In the illustrative embodiment, each waveguide 102, 106, 108, 116 is a single-mode waveguide at the frequency range in use (e.g., 1,250 nanometers to 1,350 nanometers). As used herein, a single-mode waveguide is one that supports exactly one mode at one polarization. A single-mode waveguide may not support any modes at a second polarization or it may support one mode at a second polarization, which may or may not be degenerate with the first mode, depending on the dimensions of the waveguide. In other embodiments, any or all of the waveguides 102, 106, 108, 116 may be few- or multi-mode waveguides at some or all of the frequency range in use.

The core material of each of waveguide 102, 106, 108, 116 may be any suitable material. For example, any or all of the waveguides 102, 106, 108, 116 may be silicon nitride, silicon, silicon dioxide, indium phosphide, gallium arsenide, or any other suitable material. The cladding material that forms the cladding layer 118 may be any suitable material, such as doped or undoped silicon dioxide. In the illustrative embodiment, each of the waveguides 102, 106, 108, 116 is buried with a cladding layer 118 surrounding the waveguides 102, 106, 108, 116. In other embodiments, a cladding layer 118 may only be present below the waveguides 102, 106, 108, 116, with e.g., air surrounding the waveguides 102, 106, 108, 116 on other sides. In some embodiments, there may be a substrate such as silicon below the cladding layer. The substrate layer may be far enough away from the waveguides 102, 106, 108, 116 that its index of refraction does not appreciably affect the modes in the waveguides 102, 106, 108, 116. In the illustrative embodiment, there is a relatively high contrast for the index of refraction between the core of each waveguide 102, 106, 108, 116 and the cladding 118. For example, in one embodiment, a cladding 118 of silicon dioxide may have an index of refraction of 1.45, while a waveguide 102 may have a core of silicon nitride with an index of refection of 1.99, leading to a contrast in the index of refraction of 0.54. In other embodiments, there may be a relatively low contrast for the index of refraction between the core of each waveguide 102, 106, 108, 116 and the cladding 118. For example, in one embodiment, a cladding 118 of silicon dioxide may have an index of refraction of 1.45, while a waveguide 102 of silicon dioxide doped with germanium may have an index of refraction of 1.46, leading to a contrast in the index of refraction of 0.01.

In the illustrative embodiment, the coupler 104 operates by bringing the first waveguide 102 nearby another waveguide 120 (with no input light) for a particular interaction length. Light from the first waveguide 102 then couples into the other waveguide 120 through evanescent coupling. The length of the coupling is selected to that approximately half of the light from the first waveguide 102 is coupled into the other waveguide 120. In that embodiment, the first waveguide 102 may be the same as the second waveguide 106 and the other waveguide 120 that is an input to the coupler 104 may be the same as the third waveguide 108.

In other embodiments, the coupler 104 may be any suitable structure to split light from the first waveguide 102 into the second waveguide 106 and the third waveguide 108, such as a 1×2 splitter, a Y-splitter, a 3 dB directional coupler splitter, or any other equivalent device.

The second waveguide 106 forms a path between the coupler 104 and the coupler 110 that is shorter than the path of the third waveguide 108. In the illustrative embodiment, the difference in optical path length (i.e., the physical path length times the effective index of refraction) is approximately 84.5 micrometers, which corresponds to a free spectral range of 3.55 terahertz and a spacing between channels of about 20 nanometers at 1,300 nanometers. In other embodiments, other center wavelengths may be used, such as any suitable wavelength from, e.g., 400 to 3,000 nanometers, and any suitable channel spacing may be used, such as 10 to 50,000 gigahertz. In particular, the demultiplexer system 100 may be designed to be compatible with any suitable set of channels defined by, e.g., the International Telecommunication Union in any suitable band, such as O-band, C-band, L-band, S-band, E-band, etc., using coarse wavelength division multiplexing (CWDM), dense wavelength division multiplexing (DWDM), or any other suitable wavelength multiplexing.

In the illustrative embodiment, the coupler 110 operates by bringing the second waveguide 106 near the third waveguide 108. Throughout the coupling region of the coupler 110, light may be coupled between the second waveguide 106 and the third waveguide 108. The overall structure of the coupler 104, second waveguide 106, third waveguide 108, and coupler 110 are configured such that, at the input to the grating 112 and at the low cut-off wavelength for each channel (such as low cut-off wavelength 202 for channel 200), the mode of the light is concentrated in the waveguide 108. In order to control the mode structure at the input for a given wavelength, the phase of light coming out of the coupler 104 can be controlled, the path length difference of the first waveguide 106 and second waveguide 108 may be adjusted by a fraction of a wavelength, and/or the length and/or strength of the coupler 110 can be adjusted. In the illustrative embodiment, the coupler 110 is configured so that, at the center wavelength of each channel, only the symmetric supermode of the two coupled waveguides 106, 108 is excited at the input to the grating 112. This configuration of the coupler 110 the system to have the best intensity modulation over the entire wavelength range of interest.

In the illustrative embodiment, the grating 112 (which may be an echelle grating) is constructed from the same material as the waveguides 102, 106, 108, 116. The illustrative grating 112 has the form of a slab wavelength demultiplexer, with a height that is approximately the same as the waveguides 102, 106, 108, 116. As a result, light from the waveguides 106, 108 expands into the slab of the grating 112 in one dimension while remaining confined in the other dimension. The size and shape of the grating 112 are selected so that light from the waveguides 106, 108 is allowed to expand without any significant interaction with the side walls of the slab that forms the grating 112. The length of the grating 112 is such that the light from the waveguide 106, 108 has spread into the far field relative to the input to the grating 112. The length of the grating 112 may be selected to match the grating spacing of the reflective surface 114 so that the light is reflected back to the output waveguides 116 at the desired angle and with the desired amount of dispersion. The reflective surface 114 may be blazed in order to increase the efficiency of the grating 112.

The reflective surface 114 may be any suitable surface that can reflect the input light. In one embodiment, the reflective surface 114 may be embodied as a metallic coating on the back wall of the slab of the grating 112. In another embodiment, the reflective surface 114 may be Bragg-reflector sub-gratings in each sawtooth of the reflective surface 112. The reflective surface 114 has a physical structure that causes a spatially varying phase in light impinging the reflective surface 114 such that light diffracts from the reflective surface 114. For example, in the illustrative embodiment, the reflective surface 114 has a sawtooth structure, varying the optical path length along the reflective surface 114. In other embodiments, different structures or shapes may be used.

In the illustrative embodiment, the reflective surface 114 is curved so that light coming from the waveguides 106, 108 is focused onto the waveguides 116. For example, in one embodiment, the radius of curvature of the reflective surface 114 is approximately equal to the distance between the input waveguides 106, 108 and the reflective surface 114.

It should be appreciated that, as used herein, “grating” refers to the entire structure of the grating 112, including the entire slab that is connected to the input waveguides 106, 108 and the output waveguides 116, not just the structure of the reflective surface 114 itself.

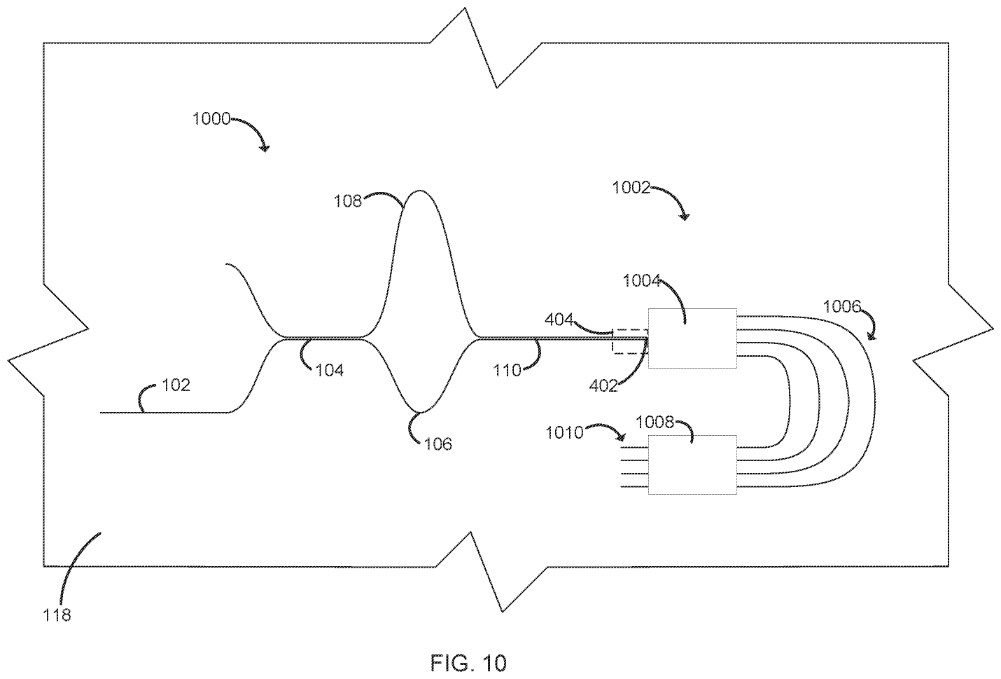

In some embodiments, the amount of contrast in the index of refraction may impact the performance of some components and positively impact the performance of others. For example, with a large contrast in the index of refraction between the material of the grating 112 and the surrounding cladding 118, the reflective surface 114 may be reflective simply due to the difference in index of refraction. With a small contrast in the index of refraction, an additional material or structure may be needed to make the reflective surface 114 sufficiently reflective. As another example, in regard to the arrayed waveguide grating 1002 discussed below in regard to FIG. 10, a low contrast in the index of refraction may make the waveguides 1006 less sensitive to small phase errors caused by, e.g., small non-uniformities in sidewall thickness. In contrast, a high contrast in the index of refraction may make the waveguides 1006 more sensitive to errors caused by, e.g., small non-uniformities in sidewall thickness, potentially limiting the overall performance of the system. For that reason, a configuration with a grating 112 may be more suitable to when there is a large difference in the index of refraction between the waveguide core material and the cladding material.

Manufacture of the demultiplexer system 100 may be done using any suitable techniques. In the illustrative embodiment, common photolithography techniques may be used. For example, in one embodiment, a substrate (such as silicon) has a silicon dioxide layer grown on it. A second layer, such as silicon, silicon nitride, doped silicon dioxide, etc., can be grown on the silicon dioxide layer, and the structures shown in FIG. 1 can be patterned onto the second layer using stand photolithographic techniques. A third layer of silicon dioxide can be grown over the structure to provide a cladding around the waveguides and other components.

It should be appreciated that the various materials used to manufacture the demultiplexer system 100 may affect the performance of the demultiplexer system 100. For example, in one embodiment, an athermal demultiplexer designed to operate over a large range of temperatures (such as, e.g., 0° C. to 80° C.) may have waveguides formed from silicon nitride, which has a relatively small shift in optical behavior over such a temperature range. For example, with a demultiplexer system 100 operating between, e.g., 1,250 nanometers and 1,370 nanometers, an athermal demultiplexer system 100 with silicon nitride waveguides may have a shift in spectra of less than 1 nanometer. In some embodiments, an athermal demultiplexer may be designed to operate over any suitable range of temperatures, such as any range within −50° C. to 150° C. Additionally or alternatively, in some embodiments, an athermal demultiplexer may be designed to have any suitable shift over its designed temperature range, such as a relative wavelength shift of less than 0.01%-1%.

The demultiplexer system 100 may be used in any suitable application and may include any suitable set of components that are not shown in FIG. 1 For example, the demultiplexer system 100 may receive a signal over the waveguide 102 from another component on the same chip, from a nearby chip, from a different component on the same device, from a remote device, etc. The signal may be split into different channels in each of the output waveguides 116. A detector connected to each output waveguide 116 can detect the signal in that channel.

The demultiplexer system 100 may include, e.g., one or more lasers or other light sources, one or more modulators, one or more detectors, etc. The demultiplexer system 100 may be included in or otherwise interact with a computer chip, a computing device, an interconnect such as a point-to-point interconnect, a router device, a network switch, a repeater, a modulator, an optical amplifier, a fiber optic device, and/or any other suitable device. It should be appreciated that the demultiplexer system 100 can also be a multiplexer system 100 simply by sending light from different the various channels into the output waveguides 116. The light from the various channels will then be combined into the waveguide 102.

Referring now to FIG. 2, in one embodiment, a demultiplexer system 100 may be able to demultiplex one multi-channel input signal into four channels with the spectra shown in FIG. 2. Each channel may have any suitable bandwidth, such as 0.1-30 nanometers. In the illustrative embodiment, each channel has a bandwidth of about 10 nanometers. The bandwidth of the passband may be defined at any suitable level. For example, in the illustrative embodiment, the passband may be defined as the band within 1 dB of the peak transmission of the channel. In other embodiments, the passband may be defined to include the band within 0.1-3 dB of the peak transmission of the channel.

It should be appreciated that the bandwidth of each channel (e.g., the bandwidth between the low cut-off wavelength 202 and the high cut-off wavelength 204) depends on the spacing between the waveguide 106 and waveguide 108 at the input of the grating 112. For example, the spectra of FIG. 2 correspond to a spacing between the waveguide 106 and the waveguide 108 of 0.25 micrometers. Increasing the spacing between the waveguide 106 and the waveguide 108 will increase the bandwidth of the channels, but it will also affect the shape of the filter. As the waveguides 106, 108 become farther apart, the spatial mode of the light corresponding to, e.g., the center wavelength 206 of channel 200 has a lowered intensity in the region between the waveguides 106, 108, reducing the coupling of that wavelength 206 to the corresponding output waveguide 116. For example, if the spacing between the waveguide 106 and the waveguide 108 is increased from 0.25 micrometers to 0.55 micrometers, the spectra of the demultiplexer system 100 will shift to that shown in FIG. 3. As shown in FIG. 3, an appreciable dip or ripple in passband of the transmission spectrum of each channel is now present. A dip or ripple of up to, e.g., 1 dB in the passband may be acceptable, but a dip or ripple in the passband that is too large may begin to affect the performance of data transfer. The dip or ripple in the passband may be, e.g., less than 0.1-1 dB, depending on the embodiment.

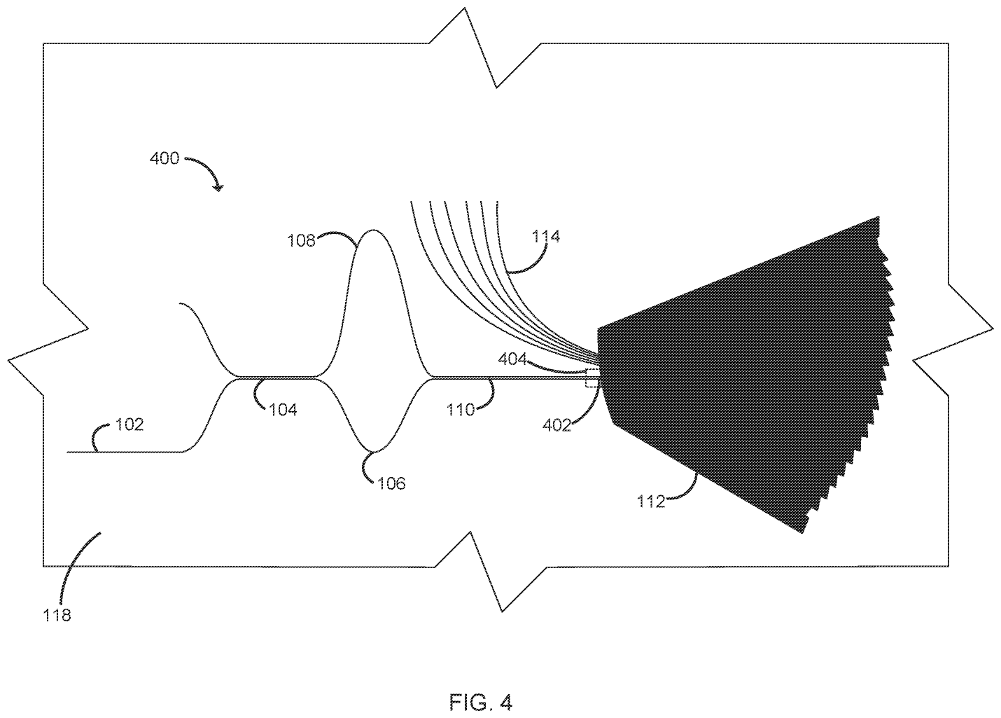

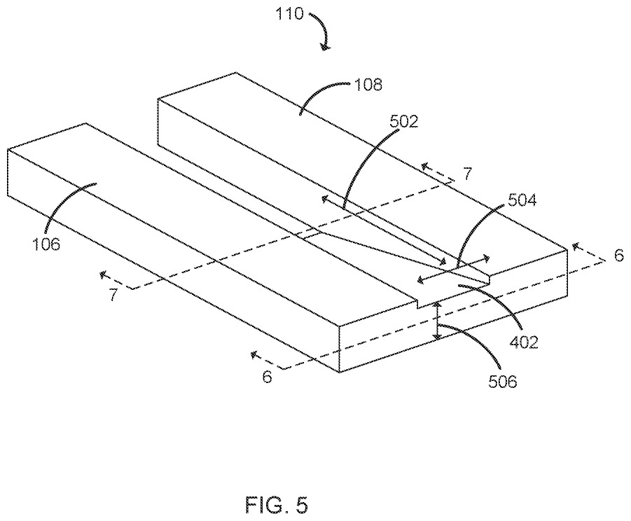

Referring now to FIG. 4, in one embodiment, in order to address the reduced coupling of the center wavelength to the corresponding output waveguide 116, a demultiplexer system 400 includes an auxiliary structure 402 that is added near the waveguides 106, 108 at the input to the grating 112. A zoomed-in view of the region 404 near the input to the grating 112 is shown in FIG. 5.

Referring now to FIG. 5, the region 404 near the input to the grating 112 shows the waveguides 106, 108 with the auxiliary structure 402 in between them. In the illustrative embodiment, the auxiliary structure 402 is embodied as a ramp formed by a vertically tapered structure using grayscale lithography. The ramp 402 is positioned between the waveguides 106, 108. The ramp begins at a distance 502 away from the input to the grating 112. The width 504 of the ramp is equal to the distance between the waveguides 106, 108. The height of the ramp begins and zero and linearly increases to a height 506 at the input to the grating 112. In the illustrative embodiment, the length 502 of the ramp is 28.6 micrometers, the width 504 is 0.55 micrometers, and the height 506 is 0.25 micrometers. The incline of the ramp is 0.5°. The dimensions of each waveguide 106, 108 in the illustrative embodiment is a width of 0.8 micrometers and a height of 0.35 micrometers. As a result, the top of the ramp 402 is 100 nanometers less than the height of the waveguides 106, 108. In other embodiments, the ramp may have any suitable length (such as 5-100 micrometers), any suitable height (such as 0.1-10 micrometers), any suitable width (such as 0.1-10 micrometers), and/or any suitable ramp angle (such as 0.1-45°). In the illustrative embodiment, in order to create the ramp, grayscale photolithography may be used. For example, in one embodiment, a grayscale mask may have a design pattern that adjusts the intensity of the light passing through to the photoresist above the desired location of the ramp, forming a developed photoresist in the form of a ramp. A dry etch with a 1:1 selectivity of the photoresist and the material being etched (e.g., silicon nitride) will result in the material being etched into the shape of the developed photoresist (i.e., into a ramp). It some embodiment, the auxiliary structure 402 may be a block shape with a similar width, length, and height as various embodiments of the ramp 402 described above but with a flat top surface that is parallel to the plane defined by the waveguides 106, 108.

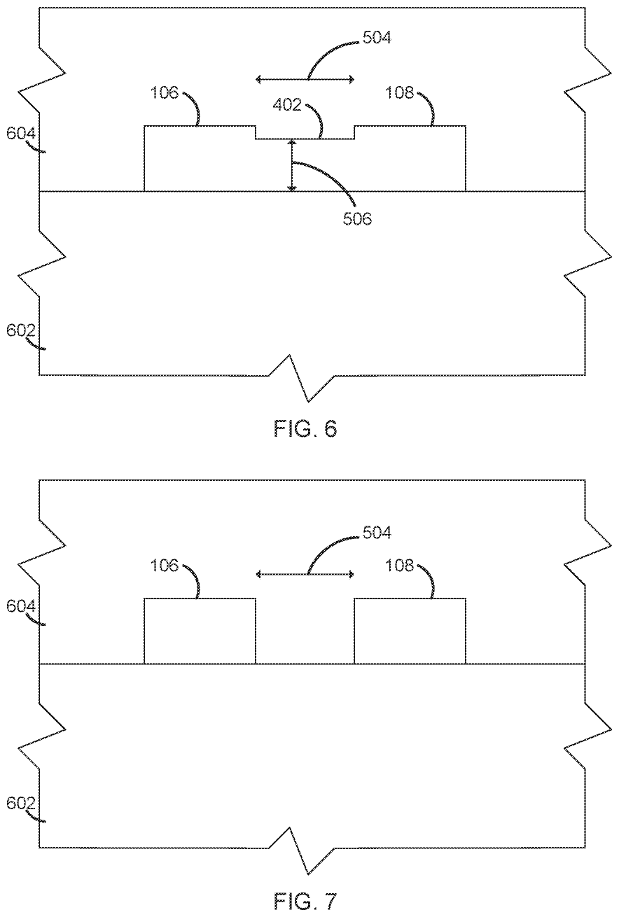

Referring now to FIG. 6, a cross-section of the ramp (taken at the cross-section labeled 6 in FIG. 5) shows the cross-section of the ramp 402 at the end of the ramp. In FIG. 7, a cross-section of the waveguides 106, 108 (taken at the cross-section labeled 7 in FIG. 5) shows the cross-section before the ramp begins increasing in height. As shown in FIGS. 6 & 7, the waveguides 106, 108 are surrounded by a bottom cladding layer 602 (on which the waveguides 106, 108 are photolithographically deposited) and a top cladding layer 604 that surrounds the other surfaces of the waveguides 106, 108. As noted above, in the illustrative embodiment, the bottom cladding layer 602 is the same as the top cladding layer 604, which may be silicon dioxide. In some embodiments, the bottom cladding layer 602 may be created using a different process from the top cladding layer 604. As a result, the top cladding layer 604 may have a slightly different index of refraction as compared to the bottom cladding layer 602. In some embodiments, the top cladding layer 604 may be a different material from the bottom cladding layer 602.

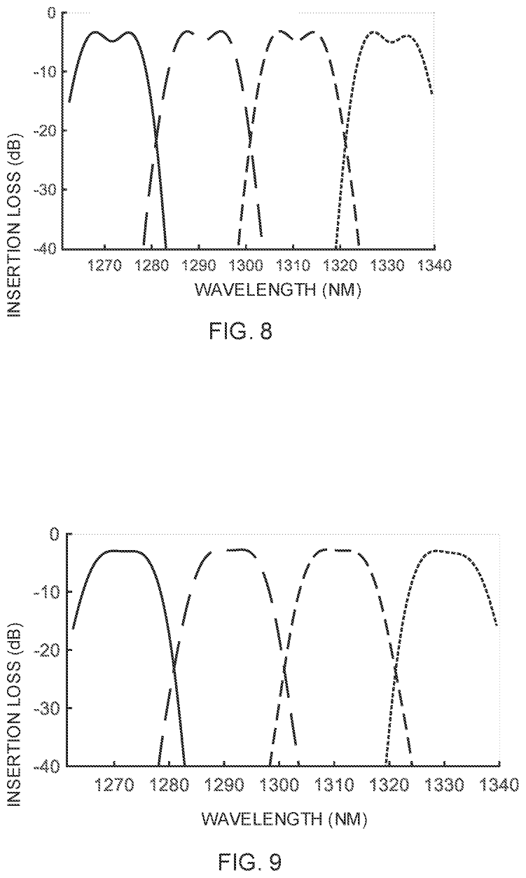

As a result of the auxiliary structure 402, the spatial modes of the superposition of the supermodes of the waveguides 106, 108 is changed. In particular, for a wavelength near the center of a channel (such as wavelength 206 for channel 200), there is a higher intensity in the region between the waveguides 106, 108 (i.e., a higher intensity where the auxiliary structure 402 is). For example, in one embodiment, with a gap between the waveguides 106, 108, the spectra of the demultiplexer system 400 may be similar to that shown in FIG. 8, with a significant dip or ripple in the middle of the passband of each spectrum. With the ramp 402 added, the spectra of the demultiplexer 400 system may be similar to that shown in FIG. 9, with the dip or ripple in the passband mostly or completely absent and, as a result, with a lower insertion loss (IL) (also called excess loss).

It should be appreciated that the ramp 402 described above is merely one possible embodiment of an auxiliary structure 402, but other embodiments of auxiliary structures 402 are possible as well. In addition to a ramp 402, other auxiliary structures 402 may transform the possible superpositions of the supermodes in the waveguides 106, 108 that lead to improved spectra for the demultiplexer system 400. For example, one or more auxiliary structures 402 may be added near (with or without a small gap) the waveguides 106, 108 near the input to the grating 112 that expand the effective size of the waveguides 106, 108. In some embodiments, the waveguides 106, 108 may be relatively close together such that there is no significant dip in intensity between the waveguides 106, 108 at the center wavelength of the channel, and auxiliary structures 402 (e.g., a ramp 402 next to the outside edge of each of the waveguides 106, 108) may be added to shift the position of the superposition of supermodes at the high and low cut-off wavelengths. The auxiliary structures 402 may have any suitable shape. For example, auxiliary structures 402 may be tapered similar to the ramp 402.

It should be appreciated that the techniques disclosed herein may be modified or included in various other embodiments. For example, in FIG. 10, in one embodiment, a demultiplexer system 1000 may include similar components as the demultiplexer system 400, except with the grating 112 replaced by a different slab wavelength demultiplexer, such as an arrayed waveguide grating 1002. The arrayed waveguide grating 1002 has a first slab expansion region 1004 in which light from the waveguides 106, 108 is allowed to expand in one dimension until it is coupled to the waveguides 1006. The waveguides 1006 have different path lengths that give a wavelength-dependent shift to the light carried in the waveguides 1006. The light leaves the waveguides 1006 and enters a second slab expansion region 1008, in which the light is focused down from the waveguides 1006 and coupled into output waveguides 1010, depending on the wavelength of the light. The spectra of the demultiplexer system 1000 may be similar to that shown in FIG. 9.

As another example, in one embodiment, a three-arm Mach-Zehnder interferometer may be used, with the waveguide of each of the three arms present in the coupler 110. Such an approach may shift the mode of light in the three waveguides such that the various wavelengths of a channel couple to the corresponding output waveguide to give spectra for the channel with good characteristics. It should be appreciated that, in some embodiments, one or more auxiliary structures 402 may be used with a three-arm Mach-Zehnder interferometer. For example, in one embodiment, three parallel waveguides may have two tapered structures such as ramps 402 formed from grayscale photolithography in between them, similar to the ramp 402 for the two-arm Mach-Zehnder interferometer shown in FIGS. 4 & 5.

As yet another example, in one embodiment, the grating 112 may have a single input waveguide, and each output of the grating may be embodied as an interferometer (similar to the interferometer formed by couplers 104 and 110 and waveguides 106 and 108). Each interferometer may have a couple to an output port of the interferometer that is dependent on both the wavelength and spatial mode of the input, operating in a similar manner as the interferometer described above in regard to FIG. 1, but in reverse.

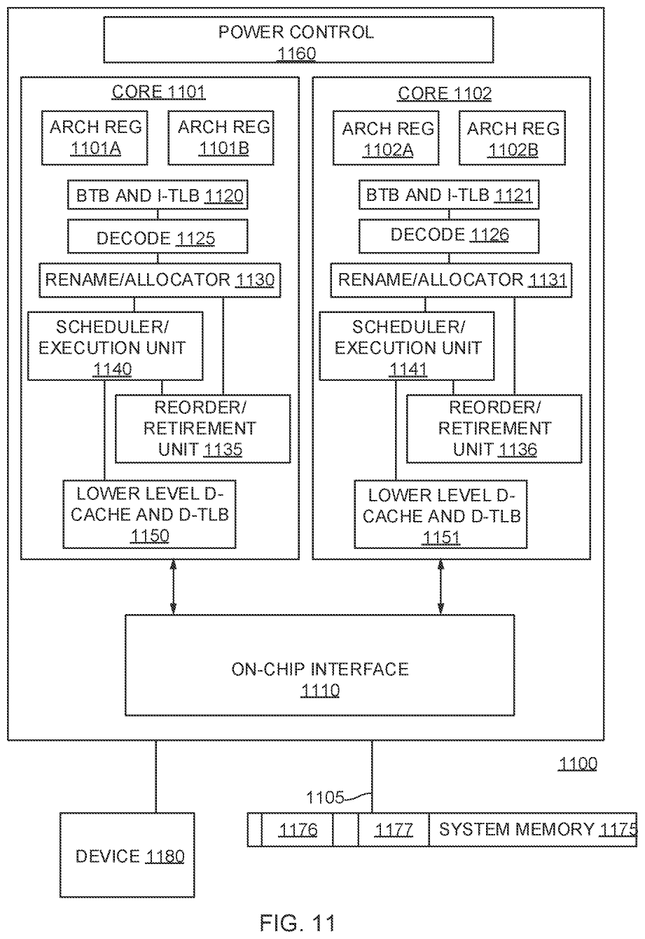

Referring to FIG. 11, an embodiment of a block diagram for a computing system including a multicore processor is depicted. Processor 1100 includes any processor or processing device, such as a microprocessor, an embedded processor, a digital signal processor (DSP), a network processor, a handheld processor, an application processor, a co-processor, a system on a chip (SOC), or other device to execute code. Processor 1100, in one embodiment, includes at least two cores—core 1101 and 1102, which may include asymmetric cores or symmetric cores (the illustrated embodiment). However, processor 1100 may include any number of processing elements that may be symmetric or asymmetric.

In one embodiment, a processing element refers to hardware or logic to support a software thread. Examples of hardware processing elements include: a thread unit, a thread slot, a thread, a process unit, a context, a context unit, a logical processor, a hardware thread, a core, and/or any other element, which is capable of holding a state for a processor, such as an execution state or architectural state. In other words, a processing element, in one embodiment, refers to any hardware capable of being independently associated with code, such as a software thread, operating system, application, or other code. A physical processor (or processor socket) typically refers to an integrated circuit, which potentially includes any number of other processing elements, such as cores or hardware threads.

A core often refers to logic located on an integrated circuit capable of maintaining an independent architectural state, wherein each independently maintained architectural state is associated with at least some dedicated execution resources. In contrast to cores, a hardware thread typically refers to any logic located on an integrated circuit capable of maintaining an independent architectural state, wherein the independently maintained architectural states share access to execution resources. As can be seen, when certain resources are shared and others are dedicated to an architectural state, the line between the nomenclature of a hardware thread and core overlaps. Yet often, a core and a hardware thread are viewed by an operating system as individual logical processors, where the operating system is able to individually schedule operations on each logical processor.

Physical processor 1100, as illustrated in FIG. 11, includes two cores—core 1101 and 1102. Here, core 1101 and 1102 are considered symmetric cores, i.e. cores with the same configurations, functional units, and/or logic. In another embodiment, core 1101 includes an out-of-order processor core, while core 1102 includes an in-order processor core. However, cores 1101 and 1102 may be individually selected from any type of core, such as a native core, a software managed core, a core adapted to execute a native Instruction Set Architecture (ISA), a core adapted to execute a translated Instruction Set Architecture (ISA), a co-designed core, or other known core. In a heterogeneous core environment (i.e. asymmetric cores), some form of translation, such as a binary translation, may be utilized to schedule or execute code on one or both cores. Yet to further the discussion, the functional units illustrated in core 1101 are described in further detail below, as the units in core 1102 operate in a similar manner in the depicted embodiment.

As depicted, core 1101 includes two hardware threads 1101a and 1101b, which may also be referred to as hardware thread slots 1101a and 1101b. Therefore, software entities, such as an operating system, in one embodiment potentially view processor 1100 as four separate processors, i.e., four logical processors or processing elements capable of executing four software threads concurrently. As alluded to above, a first thread is associated with architecture state registers 1101a, a second thread is associated with architecture state registers 1101b, a third thread may be associated with architecture state registers 1102a, and a fourth thread may be associated with architecture state registers 1102b. Here, each of the architecture state registers (1101a, 1101b, 1102a, and 1102b) may be referred to as processing elements, thread slots, or thread units, as described above. As illustrated, architecture state registers 1101a are replicated in architecture state registers 1101b, so individual architecture states/contexts are capable of being stored for logical processor 1101a and logical processor 1101b. In core 1101, other smaller resources, such as instruction pointers and renaming logic in allocator and renamer block 1130 may also be replicated for threads 1101a and 1101b. Some resources, such as re-order buffers in reorder/retirement unit 1135, ILTB 1120, load/store buffers, and queues may be shared through partitioning. Other resources, such as general purpose internal registers, page-table base register(s), low-level data-cache and data-TLB 1115, execution unit(s) 1140, and portions of out-of-order unit 1135 are potentially fully shared.

Processor 1100 often includes other resources, which may be fully shared, shared through partitioning, or dedicated by/to processing elements. In FIG. 11, an embodiment of a purely exemplary processor with illustrative logical units/resources of a processor is illustrated. Note that a processor may include, or omit, any of these functional units, as well as include any other known functional units, logic, or firmware not depicted. As illustrated, core 1101 includes a simplified, representative out-of-order (OOO) processor core. But an in-order processor may be utilized in different embodiments. The OOO core includes a branch target buffer 1120 to predict branches to be executed/taken and an instruction-translation buffer (I-TLB) 1120 to store address translation entries for instructions.

Core 1101 further includes decode module 1125 coupled to fetch unit 1120 to decode fetched elements. Fetch logic, in one embodiment, includes individual sequencers associated with thread slots 1101a, 1101b, respectively. Usually, core 1101 is associated with a first ISA, which defines/specifies instructions executable on processor 1100. Often machine code instructions that are part of the first ISA include a portion of the instruction (referred to as an opcode), which references/specifies an instruction or operation to be performed. Decode logic 1125 includes circuitry that recognizes these instructions from their opcodes and passes the decoded instructions on in the pipeline for processing as defined by the first ISA. For example, as discussed in more detail below decoders 1125, in one embodiment, include logic designed or adapted to recognize specific instructions, such as transactional instruction. As a result of the recognition by decoders 1125, the architecture or core 1101 takes specific, predefined actions to perform tasks associated with the appropriate instruction. It is important to note that any of the tasks, blocks, operations, and methods described herein may be performed in response to a single or multiple instructions; some of which may be new or old instructions. Note decoders 1126, in one embodiment, recognize the same ISA (or a subset thereof). Alternatively, in a heterogeneous core environment, decoders 1126 recognize a second ISA (either a subset of the first ISA or a distinct ISA).

In one example, allocator and renamer block 1130 includes an allocator to reserve resources, such as register files to store instruction processing results. However, threads 1101a and 1101b are potentially capable of out-of-order execution, where allocator and renamer block 1130 also reserves other resources, such as reorder buffers to track instruction results. Unit 1130 may also include a register renamer to rename program/instruction reference registers to other registers internal to processor 1100. Reorder/retirement unit 1135 includes components, such as the reorder buffers mentioned above, load buffers, and store buffers, to support out-of-order execution and later in-order retirement of instructions executed out-of-order.

Scheduler and execution unit(s) block 1140, in one embodiment, includes a scheduler unit to schedule instructions/operations on execution units. For example, a floating point instruction is scheduled on a port of an execution unit that has an available floating point execution unit. Register files associated with the execution units are also included to store information instruction processing results. Exemplary execution units include a floating point execution unit, an integer execution unit, a jump execution unit, a load execution unit, a store execution unit, and other known execution units.

Lower level data cache and data translation buffer (D-TLB) 1150 are coupled to execution unit(s) 1140. The data cache is to store recently used/operated on elements, such as data operands, which are potentially held in memory coherency states. The D-TLB is to store recent virtual/linear to physical address translations. As a specific example, a processor may include a page table structure to break physical memory into a plurality of virtual pages.

Here, cores 1101 and 1102 share access to higher-level or further-out cache, such as a second level cache associated with on-chip interface 1110. Note that higher-level or further-out refers to cache levels increasing or getting further away from the execution unit(s). In one embodiment, higher-level cache is a last-level data cache—last cache in the memory hierarchy on processor 1100—such as a second or third level data cache. However, higher level cache is not so limited, as it may be associated with or include an instruction cache. A trace cache—a type of instruction cache—instead may be coupled after decoder 1125 to store recently decoded traces. Here, an instruction potentially refers to a macro-instruction (i.e. a general instruction recognized by the decoders), which may decode into a number of micro-instructions (micro-operations).

In the depicted configuration, processor 1100 also includes on-chip interface module 1110. Historically, a memory controller, which is described in more detail below, has been included in a computing system external to processor 1100. In this scenario, on-chip interface 1110 is to communicate with devices external to processor 1100, such as system memory 1175, a chipset (often including a memory controller hub to connect to memory 1175 and an I/O controller hub to connect peripheral devices), a memory controller hub, a northbridge, or other integrated circuit. And in this scenario, bus 1105 may include any known interconnect, such as multi-drop bus, a point-to-point interconnect, a serial interconnect, a parallel bus, a coherent (e.g. cache coherent) bus, a layered protocol architecture, a differential bus, and a GTL bus.

Memory 1175 may be dedicated to processor 1100 or shared with other devices in a system. Common examples of types of memory 1175 include DRAM, SRAM, non-volatile memory (NV memory), and other known storage devices. Note that device 1180 may include a graphic accelerator, processor or card coupled to a memory controller hub, data storage coupled to an I/O controller hub, a wireless transceiver, a flash device, an audio controller, a network controller, or other known device.

Recently, however, as more logic and devices are being integrated on a single die, such as SOC, each of these devices may be incorporated on processor 1100. For example in one embodiment, a memory controller hub is on the same package and/or die with processor 1100. Here, a portion of the core (an on-core portion) 1110 includes one or more controller(s) for interfacing with other devices such as memory 1175 or a graphics device 1180. The configuration including an interconnect and controllers for interfacing with such devices is often referred to as an on-core (or un-core configuration). As an example, on-chip interface 1110 includes a ring interconnect for on-chip communication and a high-speed serial point-to-point link 1105 for off-chip communication. Yet, in the SOC environment, even more devices, such as the network interface, co-processors, memory 1175, graphics processor 1180, and any other known computer devices/interface may be integrated on a single die or integrated circuit to provide a small form factor with high functionality and low power consumption.

In one embodiment, processor 1100 is capable of executing a compiler, optimization, and/or translator code 1177 to compile, translate, and/or optimize application code 1176 to support the apparatus and methods described herein or to interface therewith. A compiler often includes a program or set of programs to translate source text/code into target text/code. Usually, compilation of program/application code with a compiler is done in multiple phases and passes to transform hi-level programming language code into low-level machine or assembly language code. Yet, single pass compilers may still be utilized for simple compilation. A compiler may utilize any known compilation techniques and perform any known compiler operations, such as lexical analysis, preprocessing, parsing, semantic analysis, code generation, code transformation, and code optimization.

Larger compilers often include multiple phases, but most often these phases are included within two general phases: (1) a front-end, i.e. generally where syntactic processing, semantic processing, and some transformation/optimization may take place, and (2) a back-end, i.e. generally where analysis, transformations, optimizations, and code generation takes place. Some compilers refer to a middle, which illustrates the blurring of delineation between a front-end and back end of a compiler. As a result, reference to insertion, association, generation, or other operation of a compiler may take place in any of the aforementioned phases or passes, as well as any other known phases or passes of a compiler. As an illustrative example, a compiler potentially inserts operations, calls, functions, etc. in one or more phases of compilation, such as insertion of calls/operations in a front-end phase of compilation and then transformation of the calls/operations into lower-level code during a transformation phase. Note that during dynamic compilation, compiler code or dynamic optimization code may insert such operations/calls, as well as optimize the code for execution during runtime. As a specific illustrative example, binary code (already compiled code) may be dynamically optimized during runtime. Here, the program code may include the dynamic optimization code, the binary code, or a combination thereof.

Similar to a compiler, a translator, such as a binary translator, translates code either statically or dynamically to optimize and/or translate code. Therefore, reference to execution of code, application code, program code, or other software environment may refer to: (1) execution of a compiler program(s), optimization code optimizer, or translator either dynamically or statically, to compile program code, to maintain software structures, to perform other operations, to optimize code, or to translate code; (2) execution of main program code including operations/calls, such as application code that has been optimized/compiled; (3) execution of other program code, such as libraries, associated with the main program code to maintain software structures, to perform other software related operations, or to optimize code; or (4) a combination thereof.

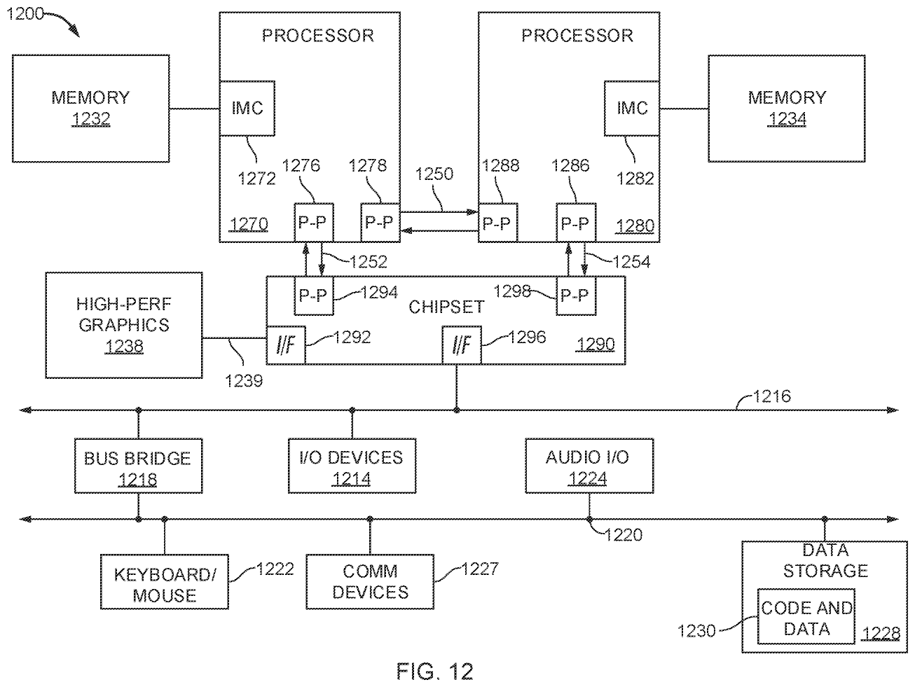

Referring now to FIG. 12, shown is a block diagram of another system 1200 in accordance with an embodiment of the present disclosure. As shown in FIG. 12, multiprocessor system 1200 is a point-to-point interconnect system, and includes a first processor 1270 and a second processor 1280 coupled via a point-to-point interconnect 1250. Each of processors 1270 and 1280 may be some version of a processor. In one embodiment, 1252 and 1254 are part of a serial, point-to-point coherent interconnect fabric, such as a high-performance architecture. As a result, aspects of the present disclosure may be implemented within the QPI architecture.

While shown with only two processors 1270, 1280, it is to be understood that the scope of the present disclosure is not so limited. In other embodiments, one or more additional processors may be present in a given processor.

Processors 1270 and 1280 are shown including integrated memory controller units 1272 and 1282, respectively. Processor 1270 also includes as part of its bus controller units point-to-point (P-P) interfaces 1276 and 1278; similarly, second processor 1280 includes P-P interfaces 1286 and 1288. Processors 1270, 1280 may exchange information via a point-to-point (P-P) interface 1250 using P-P interface circuits 1278, 1288. As shown in FIG. 12, IMCs 1272 and 1282 couple the processors to respective memories, namely a memory 1232 and a memory 1234, which may be portions of main memory locally attached to the respective processors.

Processors 1270, 1280 each exchange information with a chipset 1290 via individual P-P interfaces 1252, 1254 using point to point interface circuits 1276, 1294, 1286, 1298. Chipset 1290 also exchanges information with a high-performance graphics circuit 1238 via an interface circuit 1292 along a high-performance graphics interconnect 1239.

A shared cache (not shown) may be included in either processor or outside of both processors; yet connected with the processors via P-P interconnect, such that either or both processors' local cache information may be stored in the shared cache if a processor is placed into a low power mode.

Chipset 1290 may be coupled to a first bus 1216 via an interface 1296. In one embodiment, first bus 1216 may be a Peripheral Component Interconnect (PCI) bus, or a bus such as a PCI Express bus or another third generation I/O interconnect bus, although the scope of the present disclosure is not so limited.

As shown in FIG. 12, various I/O devices 1214 are coupled to first bus 1216, along with a bus bridge 1218 which couples first bus 1216 to a second bus 1220. In one embodiment, second bus 1220 includes a low pin count (LPC) bus. Various devices are coupled to second bus 1220 including, for example, a keyboard and/or mouse 1222, communication devices 1227 and a storage unit 1228 such as a disk drive or other mass storage device which often includes instructions/code and data 1230, in one embodiment. Further, an audio I/O 1224 is shown coupled to second bus 1220. Note that other architectures are possible, where the included components and interconnect architectures vary. For example, instead of the point-to-point architecture of FIG. 12, a system may implement a multi-drop bus or other such architecture.

It should be appreciated that, in some embodiments, a circuit board with a power tunnel may connect some or all of the various components shown in FIG. 12. Such a circuit board may include one or more power tunnels to carry current to and from any suitable component, such as the memory 1232, the processor 1270, the high-performance graphics 1238, etc.

While aspects of the present disclosure have been described with respect to a limited number of embodiments, those skilled in the art will appreciate numerous modifications and variations therefrom. It is intended that the appended claims cover all such modifications and variations as fall within the true spirit and scope of this present disclosure.

A design may go through various stages, from creation to simulation to fabrication. Data representing a design may represent the design in a number of manners. First, as is useful in simulations, the hardware may be represented using a hardware description language or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable medium, at least temporarily, an article, such as information encoded into a carrier wave, embodying techniques of embodiments of the present disclosure.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Use of the phrase ‘configured to,’ in one embodiment, refers to arranging, putting together, manufacturing, offering to sell, importing and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘to,’ capable of/to,' and or ‘operable to,’ in one embodiment, refers to some apparatus, logic, hardware, and/or element designed in such a way to enable use of the apparatus, logic, hardware, and/or element in a specified manner. Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example the decimal number ten may also be represented as a binary value of 1010 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, i.e. reset, while an updated value potentially includes a low logical value, i.e. set. Note that any combination of values may be utilized to represent any number of states.

The embodiments of methods, hardware, software, firmware or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash memory devices; electrical storage devices; optical storage devices; acoustical storage devices; other form of storage devices for holding information received from transitory (propagated) signals (e.g., carrier waves, infrared signals, digital signals); etc., which are to be distinguished from the non-transitory mediums that may receive information there from.

Instructions used to program logic to perform embodiments of the present disclosure may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the computer-readable medium includes any type of tangible machine-readable medium suitable for storing or transmitting electronic instructions or information in a form readable by a machine (e.g., a computer).

### EXAMPLES

Illustrative examples of the technologies disclosed herein are provided below. An embodiment of the technologies may include any one or more, and any combination of, the examples described below.

Example 1 includes an apparatus comprising a first waveguide; a first coupler to couple light from the first waveguide into a second waveguide and a third waveguide; a second coupler to mix light in the second waveguide and the third waveguide; a grating, wherein the second waveguide and the third waveguide are positioned as an input to the grating; and a plurality of output waveguides, wherein each of the plurality of output waveguides is configured as an output to the grating.

Example 2 includes the subject matter of Example 1, and further including one or more auxiliary structures positioned near the second waveguide and the third waveguide to modify supermodes supported by the second waveguide and the third waveguide at the input to the grating.

Example 3 includes the subject matter of any of Examples 1 and 2, and wherein the one or more auxiliary structures comprises a ramp positioned between the second waveguide and the third waveguide, wherein the ramp is to increase coupling of a center wavelength of each of a plurality of channels to a corresponding output waveguide of the plurality of output waveguides.

Example 4 includes the subject matter of any of Examples 1-3, and wherein each of the first waveguide, the second waveguide, and the third waveguide has a core material and a cladding material, wherein a difference in index of refraction between the core material and the cladding material is at least 0.1 over a wavelength range of the apparatus.

Example 5 includes the subject matter of any of Examples 1-4, and wherein the core material is silicon nitride and the cladding material is silicon dioxide.

Example 6 includes the subject matter of any of Examples 1-5, and wherein the wavelength range of the apparatus is within 1,250 and 1,370 nanometers, wherein a temperature-dependent shift in center wavelength for each of a plurality of channels of the apparatus is less than one nanometer over a range of zero to eighty degrees Celsius.

Example 7 includes the subject matter of any of Examples 1-6, and further including a plurality of detectors, wherein each of the plurality of detectors is coupled to one of the plurality of output waveguides, wherein each of the plurality of output waveguides is a single mode waveguide.

Example 8 includes the subject matter of any of Examples 1-7, and wherein a wavelength range of the apparatus is within 1,250 and 1,370 nanometers, wherein each of the plurality of output waveguides defines a channel having a center wavelength, wherein the second waveguide has a first optical path length from the first coupler to the second coupler, wherein the third waveguide has a second optical path length from the first coupler to the second coupler, wherein a difference between the first optical path length and the second optical path length defines a free spectral range of an interferometer formed by the first coupler, the second coupler, the second waveguide, and the third waveguide, and wherein the free spectral range of the interferometer is approximately equal to a spacing between center wavelengths of adjacent channels defined by the plurality of output waveguides.

Example 9 includes an apparatus comprising a first waveguide and a second waveguide, the first waveguide and the second waveguide supporting at least two supermodes; a slab wavelength demultiplexer, wherein the first waveguide and the second waveguide are positioned as an input to the slab wavelength demultiplexer; a plurality of output waveguides, wherein each of the plurality of output waveguides is configured as an output to the slab wavelength demultiplexer; and one or more auxiliary structures positioned near the first waveguide and the second waveguide to modify the at least two supermodes supported by the first waveguide and the second waveguide at the input to the slab wavelength demultiplexer.

Example 10 includes the subject matter of Example 9, and wherein the slab wavelength demultiplexer is a grating, the grating comprising a slab expansion region and a reflective surface.

Example 11 includes the subject matter of any of Examples 9 and 10, and wherein the slab wavelength demultiplexer is an arrayed waveguide grating.

Example 12 includes the subject matter of any of Examples 9-11, and wherein the one or more auxiliary structures comprises a block with a flat top positioned between the first waveguide and the second waveguide, wherein the block is to increase coupling of a center wavelength of each of a plurality of channels to a corresponding output waveguide of the plurality of output waveguides.

Example 13 includes the subject matter of any of Examples 9-12, and wherein the one or more auxiliary structures comprises a ramp positioned between the first waveguide and the second waveguide, wherein the ramp is to increase coupling of a center wavelength of each of a plurality of channels to a corresponding output waveguide of the plurality of output waveguides.

Example 14 includes the subject matter of any of Examples 9-13, and further including a coupler coupled to the first waveguide and the second waveguide, wherein the coupler, the first waveguide, and the second waveguide form an unbalanced interferometer.

Example 15 includes the subject matter of any of Examples 9-14, and further including a third waveguide between the first waveguide and the second waveguide, wherein the first waveguide, the second waveguide, and the third waveguide support at least two supermodes, wherein the one or more auxiliary structures comprises a first auxiliary structure between the first waveguide and the third waveguide and a second auxiliary structure between the second waveguide and the third waveguide.

Example 16 includes the subject matter of any of Examples 9-15, and wherein the first waveguide, second waveguide, and third waveguide form a first arm, a second arm, and a third arm, respectively, of a three-arm interferometer.

Example 17 includes the subject matter of any of Examples 9-16, and wherein each of the first waveguide and the second waveguide has a core material and a cladding material, wherein the core material is germanium-doped silica and the cladding material is silicon dioxide.

Example 18 includes a method for forming an apparatus, the method comprising photolithographically forming, on a cladding layer, a first waveguide, a second waveguide, a third waveguide, a first coupler, a second coupler, a grating, and a plurality of output waveguides, wherein the first coupler is to couple light from the first waveguide into the second waveguide and the third waveguide, wherein each of the second waveguide and the third waveguide is connected to the first coupler and the second coupler, wherein the second waveguide and the third waveguide are positioned as an input to the grating, and wherein each of the plurality of output waveguides is configured as an output to the grating.

Example 19 includes the subject matter of Example 18, and further including photolithographically forming one or more auxiliary structures positioned near the first waveguide and the second waveguide to modify supermodes supported by the first waveguide and the second waveguide at the input to the grating.

Example 20 includes the subject matter of any of Examples 18 and 19, and wherein the one or more auxiliary structures comprises a ramp positioned between the second waveguide and the third waveguide, wherein the ramp is to increase coupling of a center wavelength of each of a plurality of channels to a corresponding output waveguide of the plurality of output waveguides, wherein photolithographically forming the ramp comprising photolithographically forming the ramp with use of grayscale photolithography.

Example 21 includes the subject matter of any of Examples 18-20, and wherein each of the first waveguide, the second waveguide, and the third waveguide has a core material and a cladding material, wherein a difference in index of refraction between the core material and the cladding material is at least 0.1 over a wavelength range of the apparatus.

Example 22 includes the subject matter of any of Examples 18-21, and wherein the core material is silicon nitride and the cladding material is silicon dioxide.

Example 23 includes the subject matter of any of Examples 18-22, and wherein the wavelength range of the apparatus is within 1,250 and 1,370 nanometers, wherein a temperature-dependent shift in center wavelength for each of a plurality of channels is less than one nanometer over a range of zero to eighty degrees Celsius.

Example 24 includes the subject matter of any of Examples 18-23, and further including photolithographically forming a plurality of detectors, wherein each of the plurality of detectors is coupled to one of the plurality of output waveguides, wherein each of the plurality of output waveguides is a single mode waveguide.

Example 25 includes the subject matter of any of Examples 18-24, and wherein a wavelength range of the apparatus is within 1,250 and 1,370 nanometers, wherein each of the plurality of output waveguides defines a channel having a center wavelength, wherein the second waveguide has a first optical path length from the first coupler to the second coupler, wherein the third waveguide has a second optical path length from the first coupler to the second coupler, wherein a difference between the first optical path length and the second optical path length defines a free spectral range of an interferometer formed by the first coupler, the second coupler, the second waveguide, and the third waveguide, and wherein the free spectral range of the interferometer is approximately equal to a spacing between center wavelengths of adjacent channels defined by the plurality of output waveguides.

1. An apparatus comprising:
a first waveguide;
a first coupler to couple light from the first waveguide into a second waveguide and a third waveguide;
a second coupler to mix light in the second waveguide and the third waveguide;
a grating, wherein the second waveguide and the third waveguide are positioned as an input to the grating; and
a plurality of output waveguides, wherein each of the plurality of output waveguides is configured as an output to the grating.

2. The apparatus of claim 1, further comprising one or more auxiliary structures positioned near the second waveguide and the third waveguide to modify supermodes supported by the second waveguide and the third waveguide at the input to the grating.

3. The apparatus of claim 2, wherein the one or more auxiliary structures comprises a ramp positioned between the second waveguide and the third waveguide, wherein the ramp is to increase coupling of a center wavelength of each of a plurality of channels to a corresponding output waveguide of the plurality of output waveguides.

4. The apparatus of claim 1, wherein each of the first waveguide, the second waveguide, and the third waveguide has a core material and a cladding material, wherein a difference in index of refraction between the core material and the cladding material is at least 0.1 over a wavelength range of the apparatus.

5. The apparatus of claim 4, wherein the core material is silicon nitride and the cladding material is silicon dioxide.

6. The apparatus of claim 5, wherein the wavelength range of the apparatus is within 1,250 and 1,370 nanometers, wherein a temperature-dependent shift in center wavelength for each of a plurality of channels of the apparatus is less than one nanometer over a range of zero to eighty degrees Celsius.

7. The apparatus of claim 1, further comprising a plurality of detectors,
wherein each of the plurality of detectors is coupled to one of the plurality of output waveguides,
wherein each of the plurality of output waveguides is a single mode waveguide.

8. The apparatus of claim 1, wherein a wavelength range of the apparatus is within 1,250 and 1,370 nanometers,
wherein each of the plurality of output waveguides defines a channel having a center wavelength,
wherein the second waveguide has a first optical path length from the first coupler to the second coupler, wherein the third waveguide has a second optical path length from the first coupler to the second coupler, wherein a difference between the first optical path length and the second optical path length defines a free spectral range of an interferometer formed by the first coupler, the second coupler, the second waveguide, and the third waveguide, and
wherein the free spectral range of the interferometer is approximately equal to a spacing between center wavelengths of adjacent channels defined by the plurality of output waveguides.

9. An apparatus comprising:
a first waveguide and a second waveguide, the first waveguide and the second waveguide supporting at least two supermodes;
a slab wavelength demultiplexer, wherein the first waveguide and the second waveguide are positioned as an input to the slab wavelength demultiplexer;
a plurality of output waveguides, wherein each of the plurality of output waveguides is configured as an output to the slab wavelength demultiplexer; and
one or more auxiliary structures positioned near the first waveguide and the second waveguide to modify the at least two supermodes supported by the first waveguide and the second waveguide at the input to the slab wavelength demultiplexer.

10. The apparatus of claim 9, wherein the slab wavelength demultiplexer is a grating, the grating comprising a slab expansion region and a reflective surface.

11. The apparatus of claim 9, wherein the slab wavelength demultiplexer is an arrayed waveguide grating.

12. The apparatus of claim 9, wherein the one or more auxiliary structures comprises a block with a flat top positioned between the first waveguide and the second waveguide, wherein the block is to increase coupling of a center wavelength of each of a plurality of channels to a corresponding output waveguide of the plurality of output waveguides.

13. The apparatus of claim 9, wherein the one or more auxiliary structures comprises a ramp positioned between the first waveguide and the second waveguide, wherein the ramp is to increase coupling of a center wavelength of each of a plurality of channels to a corresponding output waveguide of the plurality of output waveguides.

14. The apparatus of claim 9, further comprising a coupler coupled to the first waveguide and the second waveguide, wherein the coupler, the first waveguide, and the second waveguide form an unbalanced interferometer.

15. The apparatus of claim 9, further comprising a third waveguide between the first waveguide and the second waveguide, wherein the first waveguide, the second waveguide, and the third waveguide support at least two supermodes,
wherein the one or more auxiliary structures comprises a first auxiliary structure between the first waveguide and the third waveguide and a second auxiliary structure between the second waveguide and the third waveguide.

16. The apparatus of claim 15, wherein the first waveguide, second waveguide, and third waveguide form a first arm, a second arm, and a third arm, respectively, of a three-arm interferometer.

17. The apparatus of claim 9, wherein each of the first waveguide and the second waveguide has a core material and a cladding material, wherein the core material is germanium-doped silica and the cladding material is silicon dioxide.

18. A method for forming an apparatus, the method comprising:
photolithographically forming, on a cladding layer, a first waveguide, a second waveguide, a third waveguide, a first coupler, a second coupler, a grating, and a plurality of output waveguides,
wherein the first coupler is to couple light from the first waveguide into the second waveguide and the third waveguide,
wherein each of the second waveguide and the third waveguide is connected to the first coupler and the second coupler,
wherein the second waveguide and the third waveguide are positioned as an input to the grating, and
wherein each of the plurality of output waveguides is configured as an output to the grating.

19. The method of claim 18, further comprising photolithographically forming one or more auxiliary structures positioned near the first waveguide and the second waveguide to modify supermodes supported by the first waveguide and the second waveguide at the input to the grating.

20. The method of claim 19, wherein the one or more auxiliary structures comprises a ramp positioned between the second waveguide and the third waveguide, wherein the ramp is to increase coupling of a center wavelength of each of a plurality of channels to a corresponding output waveguide of the plurality of output waveguides,
wherein photolithographically forming the ramp comprising photolithographically forming the ramp with use of grayscale photolithography.
